(19) United States
(12) Patent Application Publication
(10) Pub. No.: US 2026/0096322 A1
(43) Pub. Date: Apr. 2, 2026

(54) DISPLAY PANEL AND DISPLAY DEVICE

(71) Applicants: MIANYANG HKC OPTOELECTRONICS TECHNOLOGY CO., LTD., Mianyang (CN); PEKING UNIVERSITY SHENZHEN GRADUATE SCHOOL, Shenzhen (CN); HKC CORPORATION LIMITED, Shenzhen (CN)

(72) Inventors: Zhiwei YE, Mianyang (CN); Xin YUAN, Mianyang (CN); Chen CHEN, Mianyang (CN); Xiufeng ZHOU, Mianyang (CN); Haijiang YUAN, Mianyang (CN)

(21) Appl. No.: 19/338,352

(22) Filed: Sep. 24, 2025

(30) Foreign Application Priority Data
Sep. 30, 2024 (CN) 202411388502.6

(51) Int. Cl. H10K 59/131; G09G 3/3233; H10K 59/122

(52) U.S. Cl. CPC H10K 59/131; G09G 3/3233; H10K 59/122; G09G 2300/0426; G09G 2300/0819; G09G 2300/0852; G09G 2300/0861; G09G 2310/08; G09G 2320/0223; G09G 2330/02

(57) ABSTRACT

A display panel and a display device are provided. The display panel include a substrate, a pixel definition layer, a partition structure, and multiple sub-pixels. The pixel definition layer, the partition structure, and the multiple sub-pixels are are located on the substrate. The pixel definition layer defines multiple pixel openings. The multiple sub-pixels are disposed in the multiple pixel openings in one-to-one correspondence. The partition structure is disposed on the pixel definition layer and surrounds each pixel opening. The substrate includes a first conductive layer that includes multiple reference voltage lines configured to provide first reference-signals. The first reference-signals are at least indicative of controlling the multiple sub-pixels for image display. The partition structure includes a second conductive layer. The second conductive layer includes multiple first signal-lines. The multiple first signal-lines are electrically connected to the multiple reference voltage lines through a conductive portion.

### CROSS-REFERENCE TO RELATED APPLICATIONS

This application claims priority under 35 U.S.C. § 119(a) to Chinese Patent Application No. 202411388502.6, filed Sep. 30, 2024, the entire disclosure of which is incorporated herein by reference.

### TECHNICAL FIELD

This disclosure relates to the field of display technology, and in particular, to a display panel and a display device.

### BACKGROUND

An Organic Light-Emitting Diode (OLED) display device has numerous advantages, such as self-emission, low drive current, high light-emitting efficiency, fast response time, high clarity and contrast, nearly 180° viewing angle, wide operating temperature range, compatibility with flexible and large-area full-color displays, etc., and is known as the most promising display device in the industry.

### SUMMARY

In a first aspect, a display panel is provided in embodiments of the present disclosure. The display panel includes a substrate, a pixel definition layer, a partition structure, and multiple sub-pixels. The pixel definition layer, the partition structure, and the multiple sub-pixels are located on the substrate. The pixel definition layer defines multiple pixel openings. The multiple sub-pixels are disposed in the multiple pixel openings in one-to-one correspondence. The partition structure is disposed on the pixel definition layer and surrounds each of the multiple pixel openings. The substrate includes a first conductive layer. The first conductive layer includes multiple reference voltage lines. The multiple reference voltage lines are configured to provide first reference-signals. The first reference-signals are at least indicative of controlling the multiple sub-pixels for image display. The partition structure includes a second conductive layer. The second conductive layer includes multiple first signal-lines. At least a part of the pixel definition layer is provided with a conductive portion. The conductive portion penetrates through the pixel definition layer. The multiple first signal-lines are electrically connected to the multiple reference voltage lines through the conductive portion.

In a second aspect, a display device is further provided in embodiments of the present disclosure. The display device includes a power module and the display panel. The power module is configured to provide driving power to the display panel to drive the display panel to perform image display. The display panel includes a substrate, a pixel definition layer, a partition structure, and multiple sub-pixels. The pixel definition layer, the partition structure, and the multiple sub-pixels are located on the substrate. The pixel definition layer defines multiple pixel openings. The multiple sub-pixels are disposed in the multiple pixel openings in one-to-one correspondence. The partition structure is disposed on the pixel definition layer and surrounds each of the multiple pixel openings. The substrate includes a first conductive layer. The first conductive layer includes multiple reference voltage lines. The multiple reference voltage lines are configured to provide first reference-signals. The first reference-signals are at least indicative of controlling the multiple sub-pixels for image display. The partition structure includes a second conductive layer. The second conductive layer includes multiple first signal-lines. At least a part of the pixel definition layer is provided with a conductive portion. The conductive portion penetrates through the pixel definition layer. The multiple first signal-lines are electrically connected to the multiple reference voltage lines through the conductive portion.

### BRIEF DESCRIPTION OF THE DRAWINGS

To explain the technical solutions in embodiments of the present disclosure more clearly, the accompanying drawings for describing the embodiments are introduced briefly in the following. Apparently, the accompanying drawings are some embodiments of the present disclosure, and persons of ordinary skill in the art can derive other drawings from the accompanying drawings without creative efforts.

FIG. 1 is a schematic structural diagram of a display device provided in an embodiment of the present disclosure;

FIG. 2 is a schematic diagram of a planar layout of a display panel in FIG. 1;

FIG. 3 is a partial schematic diagram of a planar layout of a display region in FIG. 2;

FIG. 4 is a schematic cross-sectional structural diagram in FIG. 3, taken along A-A1;

FIG. 5 is a schematic cross-sectional structural diagram in FIG. 3, taken along B-B1;

FIG. 6 is a schematic diagram of an equivalent circuit of a pixel unit in FIG. 2;

FIG. 7 is a timing diagram of signal output in FIG. 6; and

FIG. 8 is a schematic diagram of changes in turn-on curves of drive switching transistors in FIG. 6.

Description of reference signs of the accompanying drawings: display device—100, display panel—10, power module—20, array substrate—10c, display region—10a, m data lines—S1-Sm, n scan lines—G1—Gn, first direction—F1, second direction—F2, timing control circuit 11, data driving circuit—12, scan driving circuit—13, substrate—Sub, base layer—BL, first conductive layer—M1, insulating layer—PN1, sub-pixel—15a, pixel group—15b, pixel opening P1, reference voltage line—VL, first electrode-layer—E1, second electrode-layer—E2, light-emitting layer—E3, partition structure—PS, second conductive layer—M2, eave layer—PN2, pixel definition layer—PDL, conductive portion—H, first signal—line-ML1, second signal—line ML2, signal line group—BG, first width—d1, second width—d2, pixel unit—15, driving module 151, adjustment module—152, light-emitting module—153, first signal-receiving module—154, second signal-receiving module—155, storage module—156, driving control module—157, first node—N1, second node—N2, third node—N3, fourth node—N4, first switching transistor—T1, second switching transistor—T2, third switching transistor—T3, fourth switching transistor—T4, fifth switching transistor—T5, drive switching transistor—DT, first capacitor—C1, second capacitor—C2, light-emitting element—E, scan line—G, data line—S, first adjustment-signal terminal—K1, second adjustment-signal terminal—K2, reference voltage terminal—VER, driving-voltage terminal—VDD, low-voltage terminal—VSS, first period—t1, second period—t2, third period—t3, fourth period—t4.

### DETAILED DESCRIPTION

To facilitate understanding of the present disclosure, the present disclosure will be described in details below with reference to the related drawings. The preferred implementations of the present disclosure are shown in the drawings. However, the present disclosure may be implemented in many different forms and is not limited to the implementations described herein. Rather, these implementations are provided for a thorough and complete understanding of the present disclosure.

The following descriptions of various embodiments are with reference to the accompanying figures to illustrate the specific implementations that can be implemented by the present disclosure. The serial numbers themselves, such as “first”, “second”, etc., for the components herein are only used to distinguish the described objects, and do not have any order or technical meaning. Furthermore, the “connection” and “coupling” mentioned in the present disclosure, unless otherwise specified, include both direct and indirect connection (coupling).

Directional terms mentioned in the present disclosure, such as “upper”, “lower”, “front”, “rear”, “left”, “right”, “inner”, “outer”, “side”, etc., are merely references of directions of the accompanying drawings. Accordingly, the directional terms are used for better and clearer description and understanding of the present disclosure, rather than indicating or implying that the referred device or element must have a particular orientation, be constructed and operate in a particular orientation. Therefore, it should not be construed as a limitation on the present disclosure.

In the description of the present disclosure, it should be noted that, unless otherwise expressly specified and limited, the terms “installed”, “connected”, and “coupled” should be understood in a broad sense. For example, it may be a fixed connection, a detachable connection, or an integral connection; a mechanical connection; a direct connection, an indirect connection through an intermediate medium, or an internal communication between two components. For those of ordinary skill in the art, the specific meanings of the above terms in the present disclosure can be understood in specific situations. It should be noted that the terms “first”, “second” and the like in the description, claims, and drawings of the present disclosure are used to distinguish different objects, rather than to describe a specific order.

In addition, the terms “include”, “can include”, “contain”, or “can contain” used in the present disclosure indicate the existence of the disclosed corresponding functions, operations, elements, etc., and do not limit other one or more functions, operations, components, etc. Furthermore, the terms “include” or “contain” mean corresponding features, numbers, steps, operations, elements, components, or combinations thereof disclosed in the specification, without excluding the presence or addition of one or more other features, numbers, steps, operations, elements, components, or combinations thereof, and are intended to cover the non-exclusive inclusion. In addition, when describing implementations of the present disclosure, the use of “may” means “in one or more implementations of the present disclosure”. Also, the word “exemplary”is intended to mean an example or an illustration.

Unless otherwise defined, all technical and scientific terms used herein have the same meaning as commonly understood by one of ordinary skill in the technical field to which the present disclosure belongs. The terms used herein in the specification of the present disclosure are merely for describing the implementations but are not intended to limit the present disclosure.

Since the light-emitting material of the OLED is driven by a current to emit light, when the size of the OLED display panel increases, the current driving the light-emitting material of the OLED needs to be minimized, to reduce heat generation in large-size OLED display panel. In this case, the transistors controlling the drive current are prone to threshold voltage shift, which cause fluctuations in the luminous intensity of the OLED, and affect the display effect. At present, a reference voltage is typically used in conjunction with circuit design to compensate for the threshold voltage of transistors. However, during the transmission of the reference voltage, a voltage drop occurs due to line impedance, resulting in poor threshold voltage compensation.

Accordingly, how to effectively reduce the voltage drop during the reference voltage transmission to improve the threshold voltage compensation effect is an urgent problem to be solved.

In view of the shortcomings of the described technical problem, a display panel and a display device are provided in the present disclosure to effectively eliminate a voltage drop of a reference voltage.

In a first aspect, a display panel is provided in embodiments of the present disclosure. The display panel includes a substrate, a pixel definition layer, a partition structure, and multiple sub-pixels. The pixel definition layer, the partition structure, and the multiple sub-pixels are located on the substrate. The pixel definition layer defines multiple pixel openings. The multiple sub-pixels are disposed in the multiple pixel openings in one-to-one correspondence. The partition structure is disposed on the pixel definition layer and surrounds each of the multiple pixel openings. The substrate includes a first conductive layer. The first conductive layer includes multiple reference voltage lines. The multiple reference voltage lines are configured to provide first reference-signals. The first reference-signals are at least indicative of controlling the multiple sub-pixels for image display. The partition structure includes a second conductive layer. The second conductive layer includes multiple first signal-lines. At least a part of the pixel definition layer is provided with a conductive portion. The conductive portion penetrates through the pixel definition layer. The multiple first signal-lines are electrically connected to the multiple reference voltage lines through the conductive portion.

Optionally, the second conductive layer further includes multiple second signal-lines. The multiple second signal-lines are configured to provide cathode signals to the multiple sub-pixels. Each of the multiple sub-pixels includes a first electrode-layer, a light-emitting layer, and a second electrode-layer that are sequentially laminated. The second electrode-layer is lap-jointed with adjacent two of the multiple second signal-lines. The second electrode-layer is isolated from the multiple first signal-lines. The multiple first signal-lines and the multiple second signal-lines are insulated from each other.

Optionally, at least a part of each of the multiple first signal-lines extends in one of a first direction and a second direction. At least a part of each second signal-lines extends in the other of the first direction and the second direction. The first direction is different from the second direction.

Optionally, the multiple second signal-lines are arranged sequentially in the second direction and all extend in the first direction. The multiple first signal-lines form multiple signal line groups. Each of the multiple signal line groups includes at least one first signal-lines extending in the first direction and the at least one first signal-lines extending in the second direction. First signal-lines in each of the multiple signal line groups are connected to each other.

Optionally, the partition structure further includes an eave layer. The eave layer is laminated on one side of the second conductive layer away from the pixel definition layer. In a direction parallel to the substrate, the eave layer exceeds the second conductive layer. An orthographic projection of the partition structure corresponding to each of the multiple first signal-lines on the substrate has a first width. An orthographic projection of the partition structure corresponding to each of the multiple second signal-lines on the substrate has a second width. The first width is smaller than the second width. A direction of the first width is perpendicular to an extension direction of a first signal-line corresponding to the partition structure. A direction of the second width is perpendicular to an extension direction of a second signal-line corresponding to the partition structure.

Optionally, an orthographic projection of at least a part of each of the multiple first signal-lines on the substrate is located in an orthographic projection of a corresponding reference voltage line on the substrate.

Optionally, the display panel further includes multiple data lines, multiple scan lines, and multiple pixel units arranged in an array. Each of the multiple pixel units includes at least one of the multiple sub-pixels. Each of the multiple pixel units is configured to receive a scan signal from one of the multiple scan lines and receive a data signal from one of the multiple data lines under control of the scan signal, and perform image display according to the data signal. Each of the multiple pixel units further includes a driving module, an adjustment module, and a light-emitting module. The adjustment module and the light-emitting module are electrically connected to the driving module. The adjustment module is configured to receive an adjustment signal and adjust a threshold voltage of the driving module to be within a preset range according to the adjustment signal, in a compensation phase. The driving module is configured to drive the light-emitting module to emit light according to the data signal in a light-emitting phase. The compensation phase and the light-emitting phase are two consecutive periods in one-frame image display phase.

Optionally, each of the multiple pixel units further includes a first signal-receiving module, a second signal-receiving module, and a first node. The first signal-receiving module is electrically connected to the data line, the scan line, and the first node. The first signal-receiving module is electrically connected to a first control terminal of the driving module through the first node. The first signal-receiving module is configured to receive the data signal or a second reference-signal from the data line under control of the scan signal, and transmit the data signal or the second reference-signal to the first node. The second signal-receiving module is electrically connected to the scan line and a reference voltage terminal. The second signal-receiving module is configured to receive a first reference-signal from the reference voltage terminal under control of the scan signal and transmit the first reference-signal to the driving module. The first reference-signal and the second reference-signal are indicative of adjusting the threshold voltage of the driving module by the adjustment module.

Optionally, each of the multiple pixel units further includes a storage module and a second node. The second node is electrically connected to the adjustment module, the storage module, and a second control terminal of the driving module. The adjustment signal includes a first adjustment signal and a second adjustment signal. The adjustment module is configured to control a driving-voltage terminal to charge the second node to a first potential according to the first adjustment signal. The adjustment module is configured to control the second node to discharge to the driving module through the adjustment module under control of the second adjustment signal, and adjust the threshold voltage of the driving module to a preset value when a potential of the second node drops to a second potential. The storage module is configured to maintain the potential of the second node. The preset value is a difference between the first reference-signal and the second reference-signal.

Optionally, each of the multiple pixel units further includes a driving control module. The driving control module is electrically connected to the driving-voltage terminal, a control-signal terminal, and the driving module. The driving control module is configured to receive a drive current from the driving-voltage terminal under control of a control signal output by the control-signal terminal and transmit the drive current to the driving module. The driving module is configured to control the drive current according to the data signal to drive the light-emitting module to emit light. The light-emitting module includes a light-emitting element. An anode of the light-emitting element is electrically connected to the driving module. A cathode of the light-emitting element is electrically connected to a low-voltage terminal. The light-emitting element is configured to receive the drive current and emit light according to the drive current.

Optionally, each of the multiple pixel units further includes a third node. The adjustment module includes a first switching transistor and a second switching transistor. A control terminal of the first switching transistor is electrically connected to a first adjustment-signal terminal. A first conductive terminal of the first switching transistor is electrically connected to the driving-voltage terminal. A second conductive terminal of the first switching transistor is connected to the second node. A control terminal of the second switching transistor is electrically connected to a second adjustment-signal terminal. A first conductive terminal of the second switching transistor is electrically connected to the second node. A second conductive terminal of the second switching transistor is electrically connected to the third node, and is connected to the driving module through the third node. The first switching transistor is configured to be turned on under control of the first adjustment signal to control the driving-voltage terminal to charge the second node to the first potential. The second switching transistor is configured to be turned on under control of the second adjustment signal, to control the second node to be electrically connected to the third node.

Optionally, each of the multiple pixel units further includes a third node. The adjustment module includes a second switching transistor. A control terminal of the second switching transistor is electrically connected to a second adjustment-signal terminal. A first conductive terminal of the second switching transistor is electrically connected to the second node. A second conductive terminal of the second switching transistor is electrically connected to the third node, and is electrically connected to the driving module through the third node. The second switching transistor is configured to be turned on under control of the second adjustment signal to control the second node to be electrically connected to the third node.

Optionally, each of the multiple the pixel units further includes a fourth node. The driving module includes a drive switching transistor and a first capacitor. A first control terminal of the drive switching transistor is electrically connected to the first node. A second control terminal of the drive switching transistor is electrically connected to the second node. A first conductive terminal of the drive switching transistor is electrically connected to the third node. A second conductive terminal of the drive switching transistor is electrically connected to the fourth node and electrically connected to the light-emitting module through the fourth node. The first capacitor is electrically connected between the first node and the fourth node. The drive switching transistor is configured to be turned on under control of the first node and/or the second node. The first capacitor is configured to maintain a voltage of the first node.

Optionally, the first signal-receiving module includes a third switching transistor. The second signal-receiving module includes a fourth switching transistor. The storage module includes a second capacitor. A control terminal of the third switching transistor is electrically connected to the scan line. The first conductive terminal of the third switching transistor is electrically connected to the data line. A second conductive terminal of the third switching transistor is electrically connected to the first node. The third switching transistor is configured to receive the data signal or the second reference-signal from the data line under control of the scan signal and transmit the data signal or the second reference-signal to the first node. A control terminal of the fourth switching transistor electrically connected to the scan line. A first terminal of the fourth switching transistor is electrically connected to the reference voltage terminal. A second terminal of the fourth switching transistor is electrically connected to a fourth node. The fourth switching transistor is configured to receive the first reference-signal from the reference voltage terminal under control of the scan signal and transmit the first reference-signal to the fourth node. The second capacitor is electrically connected between the second node and the fourth node. The second capacitor is configured to store a charge to maintain a voltage of the second node.

Optionally, the driving control module includes a fifth switching transistor. A control terminal of the fifth switching transistor is electrically connected to a control-signal terminal. A first conductive terminal of the fifth switching transistor is electrically connected to the driving-voltage terminal. A second conductive terminal of the fifth switching transistor is electrically connected to the first conductive terminal of the drive switching transistor. The fifth switching transistor is configured to be turned on when receiving a control signal output by the control-signal terminal to control the drive current output by the driving-voltage terminal to be transmitted to the drive switching transistor. The light-emitting module includes a light-emitting element. An anode of the light-emitting element is electrically connected to the fourth node. A cathode of the light-emitting element is electrically connected to a low-voltage terminal. The light-emitting element is configured to receive the drive current and emit light according to the drive current.

Optionally, one-frame image display performed by the pixel unit includes a sequence of a first period, a second period, a third period, and a fourth period. The second period is a compensation phase. The fourth period is a light-emitting phase. In a first period, the first switching transistor is turned on to control the second node to be charged to a first potential. The third switching transistor and the fourth switching transistor are turned on. The first node is configured to receive the second reference-signal to raise a potential of the first node to a first reference-potential. The fourth node is configured to receive the first reference-signal to raise a potential of the fourth node to a second reference-potential. The first reference-potential is higher than the second reference-potential. The first capacitor is configured to control the potential of the first node to drop to a difference between the first reference-potential and the second reference-potential. In the second period, the drive switching transistor is turned on, the second switching transistor is turned on, and the first switching transistor is turned off. The second node is configured to discharge to the drive switching transistor through the second switching transistor and the third node. When the drive switching transistor is turned off, a threshold voltage of the drive switching transistor is equal to a voltage of the first node, and at the same time, the potential of the second node drops from the first potential to the second potential, and the second capacitor is configured to store the voltage of the second node. In the third period, the second switching transistor is turned off and the data signal is transmitted to the first node through the third switching transistor and stored in the first capacitor. In the fourth period, the fifth switching transistor is turned on, the drive switching transistor is control to be turned on under control of the data signal, and the drive switching transistor is configured to receive the drive current from the fifth switching transistor and control the drive current to drive the light-emitting element to emit light.

Optionally, the first period and the second period are performed in a non-image-display phase. The third period and the fourth period are performed in an image-display phase. The non-image-display phase is a power-on non-display period.

Optionally, the first period and the second period are performed in a non-image-display phase. The third period and the fourth period are performed in an image-display phase. The non-image-display phase is a vertical blank period. The vertical blank phase is located between image-display phases of two adjacent frames. The display panel is configured to perform the first period and the second period in a vertical blank phase of each frame; or the display panel is configured to perform the first period and the second period once in a vertical blank phase of every a frames, where a is an integer greater than 1.

In a second aspect, a display device is further provided in embodiments of the present disclosure. The display device includes a power module and a display panel. The power module is configured to provide driving power to the display panel to drive the display panel to perform image display. The display panel includes a substrate, a pixel definition layer, a partition structure, and multiple sub-pixels. The pixel definition layer, the partition structure, and the multiple sub-pixels are located on the substrate. The pixel definition layer defines multiple pixel openings. The multiple sub-pixels are disposed in the multiple pixel openings in one-to-one correspondence. The partition structure is disposed on the pixel definition layer and surrounds each of the multiple pixel openings. The substrate includes a first conductive layer. The first conductive layer includes multiple reference voltage lines. The multiple reference voltage lines are configured to provide first reference-signals. The first reference-signals are at least indicative of controlling the multiple sub-pixels for image display. The partition structure includes a second conductive layer. The second conductive layer includes multiple first signal-lines. At least a part of the pixel definition layer is provided with a conductive portion. The conductive portion penetrates through the pixel definition layer. The multiple first signal-lines are electrically connected to the multiple reference voltage lines through the conductive portion.

Compared with the related art, in the embodiments of the present disclosure, the reference voltage lines in the first conductive layer are electrically connected to the first signal-lines in the second conductive layer through the conductive portions. Therefore, the first signal-line and the reference voltage line simultaneously transmit the first reference-signal, and the impedance of the reference voltage line is effectively reduced. Thus, the effect of the reference voltage drop is effectively eliminated, so that when the threshold voltage of the driving module in the pixel unit is adjusted or compensated according to the first reference-signal, the adjustment or compensation result is more accurate.

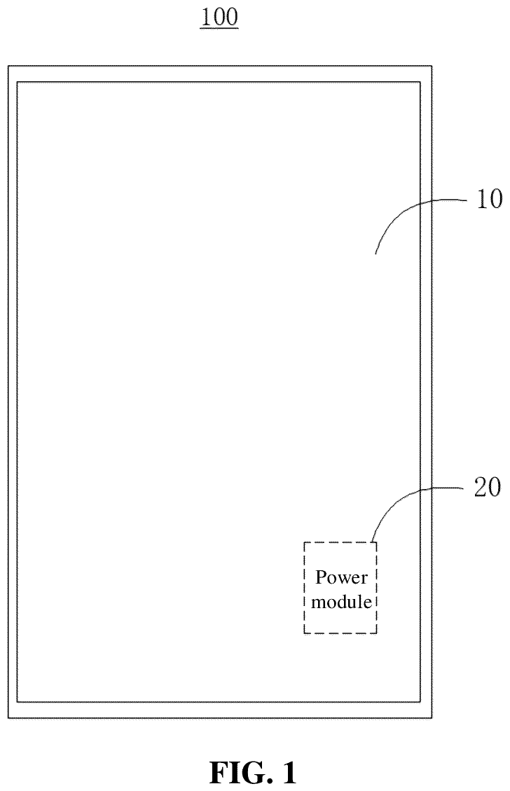

Reference can be made to FIG. 1, which is a schematic structural diagram of a display device 100 provided in a first embodiment of the present disclosure. The display device 100 includes a display panel 10 and a power module 20. The power module 20 is disposed on a rear surface of the display panel 10, i.e., a non-display surface of the display panel 10. The power module 20 is configured to provide drive current to the display panel 10 for image display.

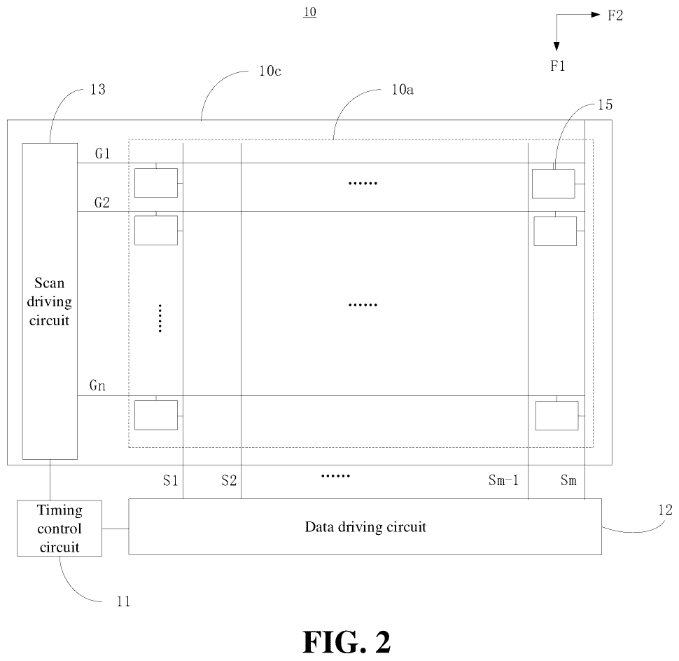

Reference can be made to FIG. 2, which is a schematic diagram of a planar layout of a display panel in FIG. 1.

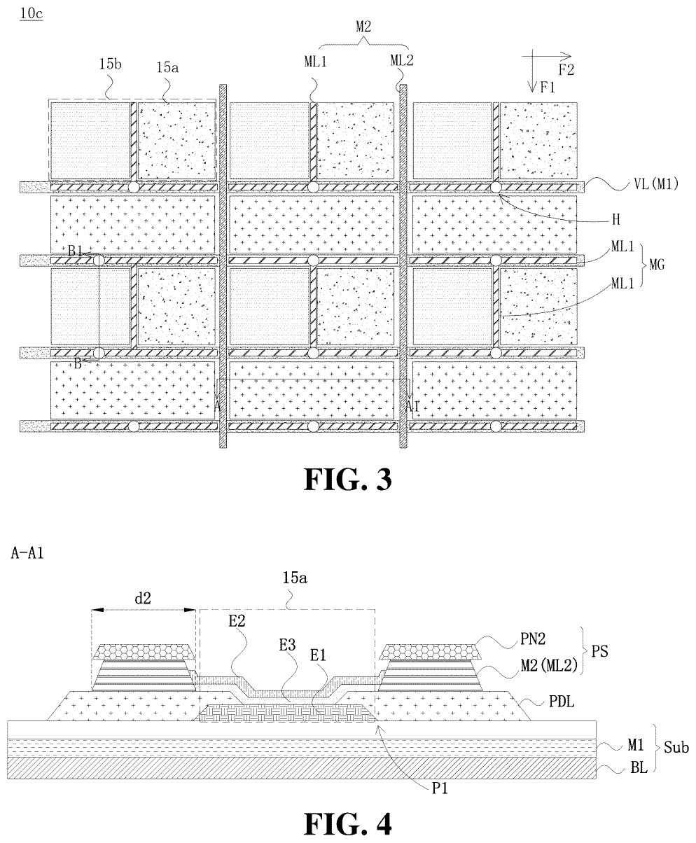

As shown in FIG. 2, the display panel 10 includes multiple pixel units 15 arranged in an array, m data lines S1-Sm, and n scan lines G1-Gn. The multiple pixel units 15 are disposed in a display region 10a of an array substrate 10c. m and n are natural numbers greater than 1. The m data lines S1-Sm extend in a first direction F1, and are insulated from each other and arranged parallel to each other in a second direction F2. The n scan lines G1-Gn extend in the second direction F2, and are insulated from each other and arranged parallel to each other in the first direction F1. The first direction F1 is different from the second direction F2, and preferably, the first direction F1 is perpendicular to the second direction F2. Each pixel unit 15 is at least connected to one data line and one scan line. The pixel unit 15 is configured to receive a scan signal from the scan line, and receive a data signal from the data line under control of the scan signal, to perform image display according to the data signal. The pixel unit 15 includes at least one sub-pixel 15a (FIG. 3). The pixel unit 15 is configured to control the sub-pixel 15a to emit light with predetermined brightness according to the data signal. The color of the light emitted by the sub-pixel may be blue, red, green, and white.

The display panel 10 further includes a timing control circuit 11, a data driving circuit 12, and a scan driving circuit 13 that are disposed in a non-display region of the array substrate 10c. The timing control circuit 11 is electrically connected to the data driving circuit 12 and the scan driving circuit 13. The timing control circuit 11 is configured to control the operation timing of the data driving circuit 12 and the scan driving circuit 13. That is, the timing control circuit 11 is configured to respectively output corresponding timing control signals to the data driving circuit 12 and the scan driving circuit 13, to control the data driving circuit 12 to output the data signal, and to control the scan driving circuit 13 to output a scan signal. The data driving circuit 12 is electrically connected to the m data lines S1-Sm, and is configured to transmit data signals (Data) for display to the pixel unit 15 in the form of data voltages through the m data lines S1-Sm. The scan driving circuit 13 is electrically connected to the n scan lines G1-Gn, and is configured to output scan signals through the n scan lines G1-Gn to control when the pixel units 15 receive the data signals.

In some embodiments, the scan driving circuit 13 may output scan signals to the n scan lines G1-Gn according to positional arrangement thereof and in accordance with a scan cycle, starting from the scan line G1, G2, . . . to Gn, to control the pixel unit 15 to receive data signals for image display. Of course, the scan signal may also be controlled to be output in other timings according to specific needs, and the present disclosure does not impose any limitation thereon.

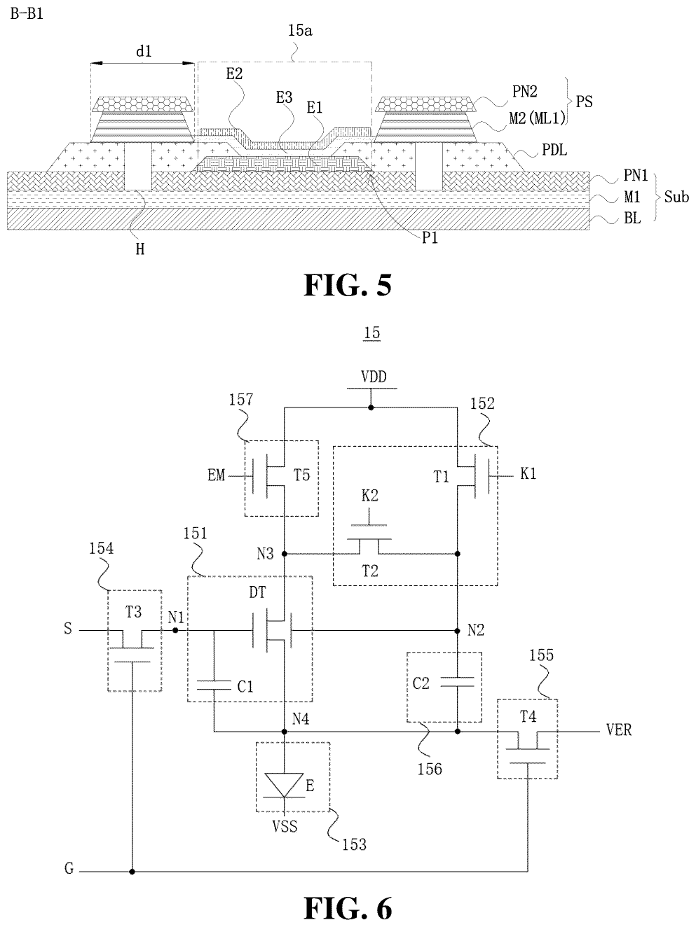

Reference can be made to FIGS. 3 to 5 together, where FIG. 3 is a partial schematic diagram of a planar layout of a display region in FIG. 2, FIG. 4 is a schematic cross-sectional structural diagram in FIG. 3, taken along A-A1, and FIG. 5 is a schematic cross-sectional structural diagram in FIG. 3, taken along B-B1.

As shown in FIG. 3, the pixel group 15b includes at least two sub-pixels 15a that are adjacent to each other and of different colors. For example, each pixel group 15b may include three sub-pixels 15a, namely a first color sub-pixel, a second color sub-pixel, and a third color sub-pixel. The first color sub-pixel, the second color sub-pixel, and the third color sub-pixel are used to respectively emit different colors of light. For example, three sub-pixels emit red light, blue light, and green light, respectively, to perform image display.

In some embodiments, the three sub-pixels 15a of the same pixel group 15b may have the same area and may also be lined up in the same direction. In other embodiments, the three sub-pixels 15a of the same pixel group 15b may have different areas and may also be arranged in different rows, and the present disclosure is not limited herein.

As shown in FIG. 4, the array substrate 10c includes a substrate Sub and a pixel definition layer PDL, a partition structure PS, and multiple sub-pixels 15a. The pixel definition layer PDL, the partition structure PS, and the multiple sub-pixels 15a are disposed on the substrate Sub. The pixel definition layer PDL defines multiple pixel openings P1. The multiple sub-pixels 15a are disposed in the multiple pixel openings P1 in one-to-one correspondence. The partition structure PS is disposed on one side of the pixel definition layer PDL away from the substrate Sub and surrounds each pixel opening P1 or each sub-pixels 15a. The substrate sub includes at least a first conductive layer M1. The first conductive layer M1 includes multiple reference voltage lines VL (FIG. 3). The multiple reference voltage lines VL are at least configured to cooperate to control the sub-pixel 15a for image display. The reference voltage lines VL are electrically coupled to the reference voltage terminal VER in the pixel unit 15 (FIG. 6) for providing the pixel unit 15 with a first reference-signal. The substrate Sub may further include a base layer BL. The first conductive layer M1 is laminated on the base layer BL. It is to be understood that a drive circuit layer (not shown) is also provided in the substrate Sub to provide the sub-pixel 15a with signals such as data signals, drive voltages, and the like, for image display. The drive circuit layer may be provided on the side of the first conductive layer M1 neighboring the sub-pixel 15a, i.e., is provided adjacent to the first electrode-layer E1, to facilitate connection of the drive circuit to the first electrode-layer E1.

The sub-pixel 15a includes a first electrode-layer E1, a second electrode-layer E2, and a light-emitting layer E3. The first electrode-layer E1, the light-emitting layer E3, and the second electrode layer E2 are sequentially laminated on the substrate Sub. The first electrode-layer E1 is connected to the drive circuit layer to receive a drive voltage from the drive circuit layer. The first electrode layer E1 may be an anode and the second electrode layer E2 may be a cathode.

Referring to FIGS. 4 and 5, the partition structure PS includes a second conductive layer M2 and an eave layer PN2. The second conductive layer M2 is disposed adjacent to the pixel definition layer PDL. The eave layer PN2 is laminated on the side of the second conductive layer M2 away from the pixel definition layer PDL. In a direction parallel to the substrate Sub, the eave layer PN2 exceeds the second signal-line ML2. In other words, an orthographic projection area of the eave layer PN2 on the substrate Sub is larger than an orthographic projection area of a top surface of the second conductive layer M2 on the substrate Sub. As a result, the partition structure PS may be applied to a maskless evaporation technology, and when forming the light-emitting layer E3, the partition structure PS may cause the light-emitting layers E3 at the adjacent pixel openings to be disconnected. In some embodiments, the cross-sectional shape of the second conductive layer M2 and the cross-sectional shape of the eave layer PN2 may be trapezoidal, and a long bottom edge of the eave layer PN2 is stacked on a short bottom edge of the second conductive layer M2 in a thickness direction. In other embodiments, the cross-sectional shape of the second conductive layer M2 and the cross-sectional shape of the eave layer PN2 may be rectangular. The eave layer PN2 may be formed using a material having an insulating effect.

Referring to FIGS. 3 and 4, the second conductive layer M2 includes multiple second signal-lines ML2. The multiple second signal-lines ML2 are used to provide cathode signals to the second electrode-layer E2. It can be seen therefrom that the multiple second signal-lines ML2 need to be electrically connected to the second electrode-layer E2 of the sub-pixel 15a, e.g., the second electrode-layer E2 is in contact with a sidewall of the second signal-line ML2. The extension and arrangement direction of the second signal-line ML2 will be described in detail later.

Referring to FIGS. 3 and 5, the second conductive layer M2 further includes multiple first signal-lines ML1. Since the first signal-line ML1 is used to transmit a first reference-signal, the first reference-signal is different from the cathode signal, the first signal-line ML1 is isolated from the second signal-line ML2 and the second electrode-layer E2, that is, the first signal-line ML1 is insulated from the second signal-line ML2 and the second electrode-layer E2, so as to avoid the problem of a short circuit occurring in a transmission path between the first reference-signal and the cathode signal. Specifically, referring to FIG. 3, from a top view, the first signal-line ML1 is spaced apart from the second signal-line ML2, and an insulating structure may also be provided between the first signal-line ML1 and the second signal-line ML2 for isolation. Referring to FIG. 5, from a cross-sectional view, the sidewall of the first signal-line ML1 is spaced apart from the second electrode-layer E2, and an insulating structure may also be provided between the sidewall of the first signal-line ML1 and the second electrode-layer E2 for isolation.

Referring to FIG. 5 again, multiple conductive portions H are provided in the pixel definition layer PDL. The multiple conductive portions H each penetrate through the pixel definition layer PDL. The multiple first signal-lines ML1 are electrically connected to the first conductive layer M1 through the multiple conductive portions H, so as to enable simultaneous transmission of the first reference-signal by the first signal-lines ML1 and the first conductive layer M1. It is to be understood that an insulating layer PN1 may further be provided on the side of the first conductive layer M1 adjacent to the pixel definition layer PDL, and the insulating layer PN1 is used to prevent a short circuit between the first conductive layer M1 and the first electrode-layer E1. In addition, the conductive portion H further penetrates through the insulating layer PN1. Comparing FIGS. 4 and 5, it can be seen that in some embodiments, the conductive portion H is provided in the pixel definition layer PDL below the first signal-line ML1, while no conductive portion H is provided in the pixel definition layer PDL below the second signal-line ML2. In other embodiments, a conductive layer for transmitting the cathode signals can also be provided in the substrate Sub in the display region, so that the conductive portion for electrically connecting the second signal-line ML2 and the conductive layer for transmitting the cathode signals may also be provided in the pixel definition layer PDL below the second signal-line ML2.

Referring to FIG. 3, from a top view, the conductive portion H may be disposed at a position corresponding to a region between two adjacent sub-pixels 15a, or the conductive portion H may be disposed at a position corresponding to a midline of the sub-pixel 15a. The present disclosure does not limit this, as long as the conductive portion H can penetrate through the pixel definition layer PDL and electrically connect the first signal-line ML2 and the first conductive layer M1. It should be noted that in order to clearly illustrate the position of the conductive portion H, the conductive portion H is enlarged in FIG. 3, which does not represent true area of the conductive portion H.

In some embodiments, an orthographic projection of at least a part of the first signal-line ML1 on the substrate Sub is located in an orthographic projection of a corresponding reference voltage line VL on the substrate Sub. For example, an extension direction of the at least part of the first signal-line ML1 may be the same as an extension direction of the reference voltage line VL, so that it may be convenient for the conductive portion H to electrically connect the first signal-line ML1 and the corresponding reference voltage line VL. The conductive portion H can be made by perforating and filling with a conductive material, without the need for additional processes to make a redundant connecting structure to electrically connect the first signal-line ML1 to the reference voltage line VL.

The position and dimensional relationship between the first signal-line ML1 and the second signal-line ML2 will be described in detail below.

Referring to FIG. 3, in some embodiments, at least a part of the first signal-line ML1 extends in one of the first direction F1 and the second direction F2; and at least a part of the second signal-line ML2 extends in the other of the first direction F1 and the second direction F2. Since the first signal-line ML1 and the second signal-line ML2 are for transmitting different electrical signals, the first signal-line ML1 and the second signal-line ML2 need to be spaced apart from each other. Therefore, different arrangement directions of the first signal-line ML1 and the second signal-line ML2 can reduce the spacing region and simplify the layout of the signal lines.

By way of example, in some embodiments, the multiple second signal-lines ML2 may extend in the first direction F1 and be sequentially arranged in the second direction F2. The multiple second signal-lines ML2 may be electrically connected at the edge of the display region by a connection line, to be uniformly supplied with an electrical signal. The multiple first signal-lines ML1 form multiple signal line groups MG. Each of the multiple signal line groups MG includes at least one first signal-line ML1 extending in the first direction F1 and at least one first signal-line ML1 extending in the second direction F2. The first signal-lines ML1 in the same signal line group are electrically connected to each other. By controlling the first signal-lines ML1 in the same signal line group MG to be electrically connected to each other, the number of the conductive portions H can be reduced. By way of example, the first signal-lines ML1 in the same signal line group MG may be formed in a shape similar to the Chinese character “ [symbol] ” or a “T”shape.

In other embodiments, the second signal-line ML2 may be extended in the second direction F2, and the first signal-line ML1 may be extended in the first direction F1. That is, the positions of the first signal-line ML1 and the second signal-line ML2 may be adaptively adjusted according to different sub-pixel arrangements, and the present disclosure does not limit this.

It should be noted that in the actual fabrication process, it is difficult to lap all sides of the second electrode-layer E2 of the one sub-pixel 15a to the sidewalls of the second conductive layer M2, and thus there may be a portion of the second conductive layer M2 that is not electrically connected to the second electrode-layer E2. In embodiments of the present disclosure, the first reference-signal is transmitted by using the second conductive layer M2 that is not electrically connected to the second electrode-layer E2. The second conductive layer M2 can thus be divided into a first signal-line ML1 and a second signal-line ML2 for transmitting different signals. Of course, in order to reduce the risk of a short circuit of the first signal-line ML1 and the second signal-line ML2, the evaporation angle can also be adjusted to increase the distance between the edge of the second electrode-layer E2 and the sidewall of the second conductive layer M2.

Referring to FIGS. 4 and 5, an orthographic projection of the partition structure PS corresponding to the first signal-line ML1 on the substrate Sub has a first width d1. An orthographic projection of the partition structure PS corresponding to the second signal-line ML2 on the substrate Sub has a second width d2. The first width d1 is smaller than the second width d2. A direction of the first width d1 is perpendicular to an extension direction of a first signal-line ML1 corresponding to the partition structure PS. A direction of the second width d2 is perpendicular to an extension direction of a second signal-line ML2 corresponding to the partition structure PS. In other words, the width of the partition structure PS in which the first signal-line ML1 for transmitting the first reference-signal is located is made narrower, so that the evaporation material of the cathode can be not lap-jointed with the sidewall of the first signal-line ML1, and the first signal-line ML1 is effectively controlled to be set at a predetermined distance apart from the second conductive layer M2. The partition structure PS in which the second signal-line ML2 for transmitting the cathode signal is located can be made wider, so that it is easier for the cathode to be lap-jointed with the second signal-line ML2. In addition, by making the partition structure PS corresponding to the first signal-line ML1 narrower, the area of the sub-pixel can be effectively enhanced, thereby enhancing the opening rate of the pixel unit.

In other embodiments, the first width d1 may also be equal to the second width d2, the lapping of the cathode with the second signal-line ML2 is also realized by adjusting the evaporation angle, and the cathode is disconnected from the first signal-line ML1.

In summary, by controlling the reference voltage line VL disposed in the first conductive layer M1 and the first signal-line ML1 disposed in the second conductive layer M2 to simultaneously transmit the first reference-signal, a parallel circuit structure is formed between the reference voltage line VL and the first signal-line ML1, and among the multiple first signal-lines ML1, thereby effectively avoiding a voltage drop caused by the impedance of the reference voltage line VL during the transmission of the reference voltage.

Reference can be made to FIG. 6, which is a schematic diagram of an equivalent circuit of a pixel unit in FIG. 2.

As shown in FIG. 6, corresponding to the driving circuit layer, the pixel unit 15 further includes a driving module 151, an adjustment module 152, and a light-emitting module 153. The driving module 151 is electrically connected to the adjustment module 152 and the light-emitting module 153. The adjustment module 152 is configured to receive an adjustment signal and adjust a threshold voltage of the driving module 151 to be within a preset range according to the adjustment signal. The driving module 151 is configured to receive a data signal and control the magnitude of a drive current transmitted to the light-emitting module 153 according to the data signal. The light-emitting module 153 is configured to emit light according to the received drive current.

By providing the adjustment module 152, threshold voltages in all the pixel units 15 can be directly adjusted to the preset range, and threshold voltages of driving modules 151 in adjacent pixel units 15 can be adjusted to be in the same preset range. Therefore, the difference in light-emitting intensity caused by variations in the threshold voltages of the driving modules 151 in the adjacent pixel units are eliminated, thereby avoiding brightness difference between the adjacent pixel units 15 and effectively improving the display effect.

In this embodiment, the pixel unit 15 further includes a first signal-receiving module 154, a second signal-receiving module 155, a storage module 156, a driving control module 157, a first node N1, a second node N2, a third node N3, and a fourth node N4. The first signal-receiving module 154 is electrically connected to the data line S, the scan line G, and the first node N1, and is electrically connected to a first control terminal of the driving module 151 through the first node N1. The first signal-receiving module 154 is configured to receive a scan signal and receive a data signal or a second reference-signal from the data line S under control of the scan signal, and transmit the data signal or the second reference-signal to the first node N1. The second reference-signal is indicative of adjusting a threshold voltage of the driving module 151 by the adjustment module 152. The data signal is provided to the driving module 151 in the image-display phase, to cause the driving module 151 to drive the light-emitting module 153 to emit light based on the data signal.

The second signal-receiving module 155 is electrically connected to the scan line S, a reference voltage terminal VER, and the fourth node N4. The second signal-receiving module 155 is configured to receive the first reference-signal from the reference voltage terminal VER under control of the scan signal, and transmit the first reference-signal to the fourth node N4 and transmit the first reference-signal through the fourth node N4 to the driving module 151. The first reference-signal is indicative of adjusting the threshold voltage of the driving module 151 by the adjustment module 152. The reference voltage terminal VER is electrically connected to the reference voltage line VL, and is configured to receive the first reference-signal from the reference voltage line VL.

The storage module 156 is electrically connected to the second node N2. The second node N2 is further electrically connected to the adjustment module 152 and a second control terminal of the driving module 151. The adjustment signals include a first adjustment signal and a second adjustment signal. The adjustment module 152 is configured to control a driving-voltage terminal to charge the second node N2 to a first potential according to the first adjustment signal, and control the second node N2 to discharge to the driving module 151 through the adjustment module according to the second adjustment signal. The adjustment module 152 is configured to adjust the threshold voltage of the driving module 151 to a preset value when a potential of the second node N2 drops from the first potential to the second potential. The preset value is a difference between the first reference-signal and the second reference-signal. The storage module 156 is configured to store a charge to maintain the voltage of the second node N2.

The driving control module 157 is electrically connected to the driving-voltage terminal VDD, a control-signal terminal EM, and the third node N3, and is electrically connected to the driving module 151 through the third node N3. The driving control module 157 is configured to receive a drive current from the driving-voltage terminal VDD in accordance with control signal output from the control-signal terminal EM and transmit the drive signal to the driving module 151 through the third node N3. The driving module 151 is configured to control the drive current according to the received data signal, to drive the light-emitting module 153 to emit light.

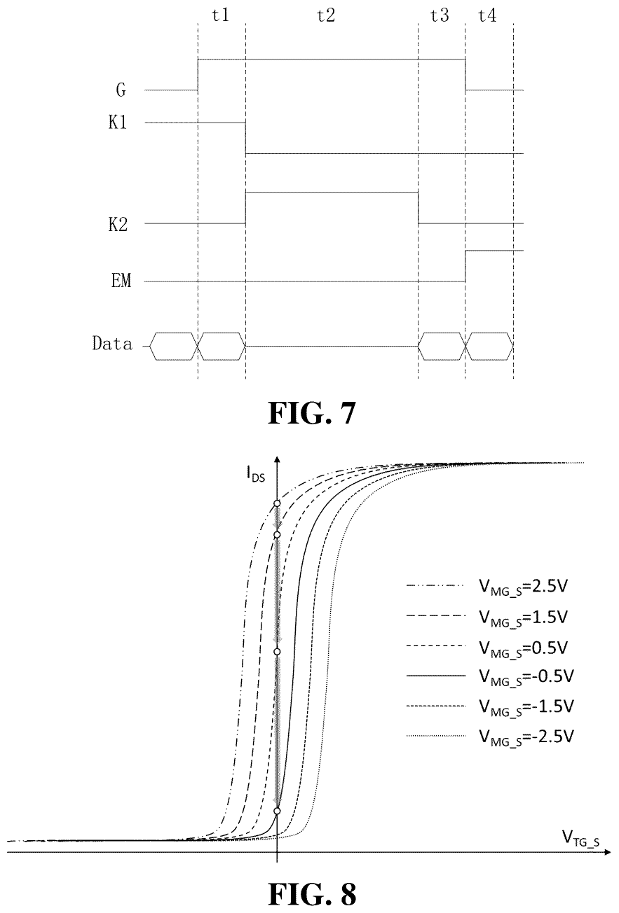

Reference can be made to FIG. 6 and FIG. 7 together, where FIG. 7 is a timing diagram of signal output in FIG. 6.

A first period t1 is an initialization phase. In the first period t1, the adjustment module 152 controls the driving-voltage terminal VDD to charge the second node N2 to a first potential, the first signal-receiving module 154 inputs a second reference-signal to the first node N1, and the second signal-receiving module 155 inputs a first reference-signal to the fourth node N4. The first reference-signal<VSS+Vel (Vel being the turn-on voltage of the light-emitting module 153), that is, the voltage of the fourth node N4 is not sufficient to control the light-emitting module 153 to emit light.

A second period t2 is a compensation phase. In the third period t2, the second node N2 discharges to the driving module 151 through the adjustment module 152 and the third node N3 until the second node N2 stops discharging to the driving module 151. Once the second node N2 stops discharging to the driving module 151, a potential of the second node N2 drops from the first potential to a second potential. The storage module 156 stores the voltage of the second node N2.

A third period t3 is a data writing phase. In the third period t3, the first signal-receiving module 154 receives the data signal and transmits the received data signal to the first node N1. At the same time, the second signal-receiving module 155 continues to input the first reference-signal to the fourth node N4 to control the fourth node N4 to maintain at the first reference voltage.

A fourth period t4 is a light-emitting phase. In the fourth period t4, the driving control module 157 receives a drive current from the driving-voltage terminal VDD and transmits the received drive current to the driving module 151, and the driving module 151 controls the drive current to drive the light-emitting module to emit light according to the data signal.

Specifically, the driving module 151 includes a drive switching transistor DT and a first capacitor C1. A first control terminal of the drive switching transistor DT is electrically connected to the first node N1. A second control terminal of the drive switching transistor DT is electrically connected to the second node N2. A first conductive terminal of the drive switching transistor DT is electrically connected to the third node N3. A second conductive terminal of the drive switching transistor DT is electrically connected to the fourth node N4, and is electrically connected to the light-emitting module 153 through the fourth node N4. In other words, the drive switching transistor DT is a dual-gate transistor having a first control terminal and a second control terminal. The first capacitor C1 of the drive switching transistor DT is electrically connected between the first node N1 and the fourth node N4. The drive switching transistor DT is used to be turned on under control of the first control terminal and/or the second control terminal, to receive a drive current from the driving control module 157 and drive the light-emitting module 153 to emit light according to the drive current.

The adjustment module 152 includes a first switching transistor T1 and a second switching transistor T2. A control terminal of the first switching transistor T1 is electrically connected to a first adjustment-signal terminal K1. A first conductive terminal of the first switching transistor T1 is electrically connected to the driving-voltage terminal VDD. A second conductive terminal of the first switching transistor T1 is connected to the second node N2. A control terminal of the second switching transistor T2 is electrically connected to a second adjustment-signal terminal K2. A first conductive terminal of the second switching transistor T2 is electrically connected to the second node N2. A second conductive terminal of the second switching transistor T2 is electrically connected to the third node N3, and is electrically connected to the drive switching transistor DT through the third node N3.

The first switching transistor T1 is configured to be turned on under control of the first adjustment signal, to control the driving-voltage terminal VDD to charge the second node N2 to the first potential. The second switching transistor T2 is configured to be turned on under control of the second adjustment signal, to control the second node N2 to be electrically connected to the first conductive terminal of the drive switching transistor DT through the third node N3. Since the second node N2 is also electrically connected to the second control terminal of the drive switching transistor D5, when the second node N2 is at the first potential, the drive switching transistor DT is turned on, so that a discharge path is formed through the second node N2, the second switching transistor T2, the third node N3, and the drive switching transistor DT, and thus the second node N2 can discharge to the drive switching transistor DT.

In another embodiment, the adjustment module 152 may consist of the second switching transistor T2. The second switching transistor T2 is configured to be turned on under control of the second adjustment signal. The driving-voltage terminal VDD is configured to charge the second node N2 to the first potential through the driving control module 157 and the second switching transistor T2. When the second node N2 is at the first potential, the drive switching transistor DT is turned on, so that a discharge path is formed through the second node N2, the second switching transistor T2, the third node N3, and the drive switching transistor DT, and thus the second node N2 can discharge to the drive switching transistor DT.

The light-emitting module 153 includes a light-emitting element E. The light-emitting element E may be an Organic Light-Emitting Diode (OLED). An anode of the light-emitting element E is electrically connected to the fourth node N4. A cathode of the light-emitting element E is electrically connected to a low-voltage terminal VSS. The light-emitting module 153 is configured to emit light according to the drive current transmitted by the drive switching transistor DT.

The first signal-receiving module 154 includes a third switching transistor T3. The second signal-receiving module 155 includes a fourth switching transistor T4. The storage module 156 includes a second capacitor C2. A control terminal of the third switching transistor T3 is electrically connected to the scan line G. A first conductive terminal of the third switching transistor T3 is electrically connected to the data line S. A second conductive terminal of the third switching transistor T3 is electrically coupled to the first node N1. The third switching transistor T3 is configured to receive the data signal or the second reference-signal from the data line S under control of the scan signal, and transmit the data signal or the second reference-signal to the first node N1 under control of the scan signal.

A control terminal of the fourth switching transistor T4 is electrically connected to the scan line G. A first terminal of the fourth switching transistor T4 is electrically connected to the reference voltage terminal VER. A second terminal of the fourth switching transistor T4 is electrically connected to the fourth node N4. The fourth switching transistor T4 is configured to receive the first reference-signal from the reference voltage terminal VER under control of the scan signal, and transmit the first reference-signal to the fourth node N4. The second capacitor C2 is electrically connected between the second node and the fourth node. The second capacitor C2 is configured to maintain a voltage of the second node N2, or to maintain a voltage difference between the second node N2 and the fourth node N4.

The driving control module 157 includes a fifth switching transistor T5. A control terminal of the fifth switching transistor T5 is electrically connected to the control-signal terminal EM. A first conductive terminal of the fifth switching transistor T5 is electrically connected to the driving-voltage terminal VDD. A second conductive terminal of the fifth switching transistor T5 is electrically connected to the first conductive terminal of the drive switching transistor DT. The fifth switching transistor T5 is configured to be turned on when receiving the control signal, to control the drive current output by the driving-voltage terminal VDD to be transmitted to the drive switching transistor DT.

In embodiments of the present disclosure, in the first period t1, the second switching transistor T2 and the fifth switching transistor T5 are turned on, the second node N2 is charged to the first potential by the driving-voltage terminal VDD, and at the same time, the third switching transistor T3 and the fourth switching transistor T4 are turned on, the first node N1 is configured to receive the first reference-signal to raise a potential of the first node N1 to a first reference-potential, and the fourth node N4 is configured to receive the second reference-signal to raise a potential of the fourth node N4 to a second reference-potential. In the second period t2, the fifth switching transistor T5 is turned off, the second switching transistor T2 and the drive switching transistor DT are turned on, the second node N2 is configured to discharge to the drive switching transistor DT through the second switching transistor T2 and the third node N3, to drop the potential of the second node N2 from the first potential to the second potential, to control the drive switching transistor DT to be turned off, a threshold voltage of the drive switching transistor DT is adjusted to a preset value when the drive switching transistor DT is turned off, and the second capacitor C2 is configured to maintain the voltage of the second node N2. In the third period t3, the second switching transistor T2 is turned off and the data signal is transmitted to the first node N1 through the third switching transistor T3 and stored in the first capacitor C1. In the fourth period t4, the fifth switching transistor T5 is turned on, the drive switching transistor DT is controlled to be turned on under control of the data signal, and the drive switching transistor DT is configured to receive the drive current from the fifth switching transistor T5 and control the drive current to drive the light-emitting element E to emit light.

As shown in FIG. 7, in the first period t1, the first adjustment-signal terminal K1 controls the first switching transistor T1 to be turned on, to control the driving-voltage terminal VDD to charge the second node N2 to the first potential. At the same time, the third switching transistor T3 and the fourth switching transistor T4 are turned on under control of the scan signal, the third switching transistor T3 receives the second reference-signal from the data line S and transmits the second reference-signal to the first node N1, and the fourth switching transistor T4 receives the first reference-signal from the reference voltage terminal VER and transmits the first reference-signal to the fourth node N4. The second reference voltage (second reference-signal) is greater than or equal to the first reference voltage (first reference-signal), and VER<VSS+Vel, that is, the first reference voltage transmitted to the fourth node N4 is not sufficient to drive the light-emitting element E to emit light. When the adjustment module 152 consists of the second switching transistor T2, the driving-voltage terminal VDD charges the second node N2 to the first potential through the fifth switching transistor T5 and the second switching transistor T2.

In the second period t2, the second switching transistor T2 is turned on under control of the second adjustment signal, the drive switching transistor DT is turned on under control of the first node N1 and the second node N2, and a discharge path is formed through the second node N2, the second switching transistor T2, the third node N3, and the drive switching transistor DT. Reference can be made to FIG. 8, which is a schematic diagram of changes in turn-on curves of drive switching transistors in FIG. 6. V_{TG_S} is a voltage difference between the first control terminal of the drive switching transistor DT and the second conductive terminal of the drive switching transistor DT, that is, a voltage difference between a first gate and a source of the drive switching transistor DT, also known as a voltage difference between the first node N1 and the fourth node N4. V_{MG_S} is a voltage difference between the second control terminal of the drive switching transistor DT and the second conductive terminal of the drive switching transistor DT, that is, a voltage difference between a second gate of the drive switching transistor DT and the source of the drive switching transistor DT, also known as a voltage difference between the second node N2 and the fourth node N4. I_{DS} is the amount of current flowing through the drive switching transistor DT. In the following, the discharge process is described in detail based on the curve of V_{MG_S}=2.5 V. At the beginning of the second period t2, taking V_{MG_S}=2.5V (V_{N2}−V_{N4}=2.5 V) and V_{TG_S}=0 V (V_{N1}−V_{N4}=0 V) as an example, at this time, I_{DS} [symbol] 0, and the drive switching transistor DT is in an on state. As the second period t2 proceeds, the second node N2 discharges to the fourth node N4 through the second switching transistor T2 and the drive switching transistor DT, so that the voltage of the second node N2 gradually decreases and the voltage of the fourth node N4 gradually increase. At this time, the voltage difference (i.e., V_{MG_S}) between the second node N2 and the fourth node N4 gradually decreases. After the voltage of the second node N2 decreases to less than the voltage of the fourth node N4, the voltage difference between the second node N2 and the fourth node N4 gradually increases again, that is, V_{MG_S} gradually increases again. In other words, the whole discharge process can be referred to the arrow symbol on the vertical coordinate axis, that is, V_{TG_S} is unchanged, while V_{MG_S} first gradually decreases and then gradually increases, and in the process, I_{DS} gradually decreases.

When the voltage of the second node N2 or the voltage of the second control terminal of the drive switching transistor DT is a preset voltage V_{MG}, the voltage of the first control terminal of the drive switching transistor DT (V_{TG_S}) is equal to the threshold voltage Vth of the drive switching transistor DT. In this embodiment, Vth=V_{TG_S}=0. In other embodiments, V_{TG_S} (V_{N1}−V_{N4}) may be set to other values in the first period t1. Since V_{TG_S} is maintained constant in the second period t2, accordingly, the threshold voltage Vth may also be other values. That is, the threshold voltage Vth may be set according to specific needs, and the present disclosure does not limit this.

In the third period t3, the second switching transistor T2 is turned off under control of the second adjustment signal, the second capacitor C2 stores a charge to maintain the voltage difference between the second node N2 and the fourth node N4, and the data voltage V_{Data} (data signal) is output from the data line S to the first node N1 through the third switching transistor T3. At this time, the reference voltage terminal VER provides a reference voltage for the fourth node N4, and V_{TG_S}=V_{N1}−V_{N4}=V_{Data}−V_{ER}.

In the fourth period t4, the scan line G stops transmitting the scan signal, to control the third switching transistor T3 and the fourth switching transistor T4 to be turned off, the input voltage V_{Data} written from the data line S is transmitted to the first node N1, and the first capacitor C1 maintains the voltage of the first node N1. At the same time, the control-signal terminal EM controls the fifth switching transistor T5 to be turned on, so that a path is formed between the driving-voltage terminal VDD and the low voltage terminal VSS. The drive switching transistor DT and the light-emitting element E divide the voltage across this path, and the voltage of the fourth node N4 rises to V_{E}+VSS to drive the light-emitting element E to emit light, where V_{E} is a voltage for driving the light-emitting element E to emit light. As the voltage of the fourth node N4 rises, the voltage of the first node N1 increases to V_{Data}+V_{E}+VSS−V_{ER} due to a coupling effect of the first capacitor C1, and the voltage of the second node N2 increases to V_{MG}+V_{E}+VSS−V_{ER} due to a coupling effect of the second capacitor C2. At this time, the current I flowing through the light-emitting element satisfies: I=(k/2)(V_{TG_S}−Vth)²=(k/2)[(1−α)(V_{Data}−V_{ER}−Vₜₕ)]2, where since Vₜₕ=V_{TG_S}=0, I=(k/2)[(1−α)(V_{Data}−V_{ER})]². In the initialization phase (first period t1), the first reference voltage written from the data line S can be set according to the specific needs. If the voltage written is Vx, under control of the preset voltage V_{MG}, the threshold voltage of the first switching transistor satisfies: Vₜₕ=Vx 31 V_{ER}. In other words, by adjusting the voltage Vx written in the initialization phase, the IDVG curve (FIG. 4) of the first switching transistor T1 can be adjusted to be shifted, so that the brightness can be adjusted, that is, the compensation for the brightness of the pixel unit can be realized by controlling the voltage written in the initialization phase.

In the non-image-display phase, the pixel unit 15 performs the first period t1 and the second period t2 to adjust the threshold voltage of the drive switching transistor DT. In the image-display phase for each frame, the pixel unit 15 performs the third period t3 and the fourth period t4 to receive a data signal for image display. The non-image-display phase may be a power-on non-display period of the display panel 10 and a vertical blank period between any two adjacent frames.

When the first period t1 and the second period t2 are performed in the non-display period, all pixel units 15 across the display panel may be controlled to perform compensation at the same time, that is, to perform full-panel compensation. Alternatively, the first period t1 and the second period t2 are performed in the vertical blank period of every a frames, where a is an integer greater than or equal to 1. That is, the full-plane compensation can be performed on the threshold voltage of the drive switching transistor after the display of successive multiple frames of images. In other words, the first period t1 and the second period t2 in the first compensation mode can be performed in the non-image-display phase, thereby completing the process of setting the threshold voltage of the drive switching transistor DT. In this way, instead of performing the first period t1 and the second period t2 in the display phase, the third period t3 and the fourth period t4 are performed in the display phase, thereby completing the data writing and light-emitting process. Compared with the line-by-line compensation mode, the load on the transmission path of the first reference-signal in the full-plane compensation mode is larger. Therefore, in the present disclosure, the reference voltage line VL disposed in the first conductive layer M1 and the first signal-line ML1 disposed in the second conductive layer M2 are controlled to simultaneously transmit the first reference-signal, in coordination with the full-plane compensation performed by the display panel 10 in the non-image-display phase, so that the influence of line impedance is reduced, and the compensation effect on the threshold voltage is greatly improved.

Of course, a line-by-line compensation mode may also be used. During the line-by-line compensation, the first signal-line ML1 is also conducive to reducing the line impedance. The line-by-line compensation can be understood as a process in which the pixel unit 15 performs the first period t1 to the fourth period t4 sequentially during each frame of image display process (display frame), with the compensation phase and the data writing phase being performed line-by-line.

The embodiments of the present disclosure also provide the effect of increasing the threshold voltage compensation range. The specific principle is as follows: according to the aforementioned current formula, I=(k/2)(V_{TG_S}−Vth)². After the compensation phase and the data writing phase in the embodiments of the present disclosure, V_{TG_S}=V_{Data}−V_{ER}, that is to say, V_{TG_S} does not include Vth. In contrast, in the conventional solution in which the driving transistor is a single-gate type, after the compensation phase and the data writing phase, V_{TG_S}=V_{Data}+Vth −Vint, where Vint can be interpreted as a reference voltage similar to VER, and VTG_S (the voltage difference between the gate and the source) includes Vth, that is, the input data signal contains the voltage signal for compensating the threshold voltage. Due to the presence of Vth, the writing range of the data signal Data is squeezed and occupied, and thus the compensation range of Vth is limited to avoid affecting the Data range. In contrast, in the embodiments of the present disclosure, VTG_S does not include Vth, that is, the voltage signal for compensating the threshold voltage is no longer included in the written data signal, so even if the range of Vth is set to a large extent, the writing range of VData is not squeezed and occupied. In addition, since the pixel unit 15 can be compensated in the non-image-display phase in the embodiments of the present disclosure, the occupancy of the image display phase is reduced, and the threshold voltage of the driving module 151 can be adjusted and compensated in the case of displaying images at intervals of multiple frames. Therefore, the compensation time is shortened, and the image display duration of each frame is increased, which can in turn effectively improve the image refresh rate.

It may be understood that application of the present disclosure is not limited to the above examples. For those of ordinary skill in the art, improvements or changes can be made according to the above description, and these improvements and changes all fall within the protection scope of the appended claims of the present disclosure.

What is claimed is:

1. A display panel, comprising a substrate, a pixel definition layer, a partition structure, and a plurality of sub-pixels, wherein the pixel definition layer, the partition structure, and the plurality of sub-pixels are located on the substrate;
the pixel definition layer defines a plurality of pixel openings;
the plurality of sub-pixels are disposed in the plurality of pixel openings in one-to-one correspondence;
the partition structure is disposed on the pixel definition layer and surrounds each of the plurality of pixel openings;
the substrate comprises a first conductive layer, the first conductive layer comprises a plurality of reference voltage lines, and the plurality of reference voltage lines are configured to provide first reference-signals; and the first reference-signals are at least indicative of controlling the plurality of sub-pixels for image display; and
the partition structure comprises a second conductive layer, the second conductive layer comprises a plurality of first signal-lines; at least a part of the pixel definition layer is provided with a conductive portion, and the conductive portion penetrates through the pixel definition layer; and the plurality of first signal-lines are electrically connected to the plurality of reference voltage lines through the conductive portion.

2. The display panel of claim 1, wherein the second conductive layer further comprises a plurality of second signal-lines, and the plurality of second signal-lines are configured to provide cathode signals to the plurality of sub-pixels; and
each of the plurality of sub-pixels comprises a first electrode-layer, a light-emitting layer, and a second electrode-layer that are sequentially laminated, the second electrode-layer is lap-jointed with adjacent two of the plurality of second signal-lines, and the second electrode-layer is isolated from the plurality of first signal-lines; and the plurality of first signal-lines and the plurality of second signal-lines are insulated from each other.

3. The display panel of claim 2, wherein at least a part of each of the plurality of first signal-lines extends in one of a first direction and a second direction, at least a part of each second signal-lines extends in the other of the first direction and the second direction, and the first direction is different from the second direction.

4. The display panel of claim 3, wherein the plurality of second signal-lines are arranged sequentially in the second direction and all extend in the first direction; the plurality of first signal-lines form a plurality of signal line groups, each of the plurality of signal line groups comprises at least one first signal-lines extending in the first direction and the at least one first signal-lines extending in the second direction, and first signal-lines in each of the plurality of signal line groups are connected to each other.

5. The display panel of claim 2, wherein the partition structure further comprises an eave layer, the eave layer is laminated on one side of the second conductive layer away from the pixel definition layer, and in a direction parallel to the substrate, the eave layer exceeds the second conductive layer; and
an orthographic projection of the partition structure corresponding to each of the plurality of first signal-lines on the substrate has a first width; an orthographic projection of the partition structure corresponding to each of the plurality of second signal-lines on the substrate has a second width, and the first width is smaller than the second width; and a direction of the first width is perpendicular to an extension direction of a first signal-line corresponding to the partition structure, and a direction of the second width is perpendicular to an extension direction of a second signal-line corresponding to the partition structure.

6. The display panel of claim 1, wherein an orthographic projection of at least a part of each of the plurality of first signal-lines on the substrate is located in an orthographic projection of a corresponding reference voltage line on the substrate.

7. The display panel of claim 1, wherein the display panel further comprises a plurality of data lines, a plurality of scan lines, and a plurality of pixel units arranged in an array, wherein each of the plurality of pixel units comprises at least one of the plurality of sub-pixels, and each of the plurality of pixel units is configured to receive a scan signal from one of the plurality of scan lines and receive a data signal from one of the plurality of data lines under control of the scan signal, and perform image display according to the data signal; and
each of the plurality of pixel units further comprises a driving module, an adjustment module, and a light-emitting module, the adjustment module and the light-emitting module are electrically connected to the driving module, the adjustment module is configured to receive an adjustment signal and adjust a threshold voltage of the driving module to be within a preset range according to the adjustment signal, and the driving module is configured to drive the light-emitting module to emit light according to the data signal.

8. The display panel of claim 7, wherein each of the plurality of pixel units further comprises a first signal-receiving module, a second signal-receiving module, and a first node, the first signal-receiving module is electrically connected to the data line, the scan line, and the first node, the first signal-receiving module is electrically connected to a first control terminal of the driving module through the first node, the first signal-receiving module is configured to receive the data signal or a second reference-signal from the data line under control of the scan signal, and transmit the data signal or the second reference-signal to the first node; and
the second signal-receiving module is electrically connected to the scan line and a reference voltage terminal, the second signal-receiving module is configured to receive a first reference-signal from the reference voltage terminal under control of the scan signal and transmit the first reference-signal to the driving module, and the first reference-signal and the second reference-signal are indicative of adjusting the threshold voltage of the driving module by the adjustment module.

9. The display panel of claim 8, wherein each of the plurality of pixel units further comprises a storage module and a second node, the second node is electrically connected to the adjustment module, the storage module, and a second control terminal of the driving module, and the adjustment signal comprises a first adjustment signal and a second adjustment signal; and
the adjustment module is configured to control a driving-voltage terminal to charge the second node to a first potential according to the first adjustment signal, the adjustment module is configured to control the second node to discharge to the driving module through the adjustment module under control of the second adjustment signal, and adjust the threshold voltage of the driving module to a preset value when a potential of the second node drops to a second potential, the storage module is configured to maintain the potential of the second node, and the preset value is a difference between the first reference-signal and the second reference-signal.

10. The display panel of claim 9, wherein each of the plurality of pixel units further comprises a driving control module, the driving control module is electrically connected to the driving-voltage terminal, a control-signal terminal, and the driving module, the driving control module is configured to receive a drive current from the driving-voltage terminal under control of a control signal output by the control-signal terminal and transmit the drive current to the driving module, and the driving module is configured to control the drive current according to the data signal to drive the light-emitting module to emit light; and
the light-emitting module comprises a light-emitting element, an anode of the light-emitting element is electrically connected to the driving module, a cathode of the light-emitting element is electrically connected to a low-voltage terminal, and the light-emitting element is configured to receive the drive current and emit light according to the drive current.

11. The display panel of claim 9, wherein each of the plurality of pixel units further comprises a third node, the adjustment module comprises a first switching transistor and a second switching transistor, a control terminal of the first switching transistor is electrically connected to a first adjustment-signal terminal, a first conductive terminal of the first switching transistor is electrically connected to the driving-voltage terminal, a second conductive terminal of the first switching transistor is connected to the second node, a control terminal of the second switching transistor is electrically connected to a second adjustment-signal terminal, a first conductive terminal of the second switching transistor is electrically connected to the second node, and a second conductive terminal of the second switching transistor is electrically connected to the third node, and is connected to the driving module through the third node; and
the first switching transistor is configured to be turned on under control of the first adjustment signal to control the driving-voltage terminal to charge the second node to the first potential, and the second switching transistor is configured to be turned on under control of the second adjustment signal to control the second node to be electrically connected to the third node.

12. The display panel of claim 10, wherein each of the plurality of pixel units further comprises a third node, the adjustment module comprises a second switching transistor, a control terminal of the second switching transistor is electrically connected to a second adjustment-signal terminal, a first conductive terminal of the second switching transistor is electrically connected to the second node, and a second conductive terminal of the second switching transistor is electrically connected to the third node, and is electrically connected to the driving module through the third node; and
the second switching transistor is configured to be turned on under control of the second adjustment signal to control the second node to be electrically connected to the third node.

13. The display panel of claim 11, wherein each of the plurality of the pixel units further comprises a fourth node, the driving module comprises a drive switching transistor and a first capacitor, a first control terminal of the drive switching transistor is electrically connected to the first node, a second control terminal of the drive switching transistor is electrically connected to the second node, a first conductive terminal of the drive switching transistor is electrically connected to the third node, a second conductive terminal of the drive switching transistor is electrically connected to the fourth node and electrically connected to the light-emitting module through the fourth node, the first capacitor is electrically connected between the first node and the fourth node, the drive switching transistor is configured to be turned on under control of the first node and/or the second node, and the first capacitor is configured to maintain a voltage of the first node.

14. The display panel of claim 13, wherein the first signal-receiving module comprises a third switching transistor, the second signal-receiving module comprises a fourth switching transistor, the storage module comprises a second capacitor, a control terminal of the third switching transistor is electrically connected to the scan line, the first conductive terminal of the third switching transistor is electrically connected to the data line, a second conductive terminal of the third switching transistor is electrically connected to the first node, and the third switching transistor is configured to receive the data signal or the second reference-signal from the data line under control of the scan signal and transmit the data signal or the second reference-signal to the first node; and
a control terminal of the fourth switching transistor electrically connected to the scan line, a first conductive terminal of the fourth switching trantor is electrically connected to the reference voltage terminal, a second conductive terminal of the fourth switching transistor is electrically connected to a fourth node, the fourth switching transistor is configured to receive the first reference-signal from the reference voltage terminal under control of the scan signal and transmit the first reference-signal to the fourth node; and the second capacitor is electrically connected between the second node and the fourth node, and the second capacitor is configured to store a charge to maintain a voltage of the second node.

15. The display panel of claim 14, wherein the driving control module comprises a fifth switching transistor, a control terminal of the fifth switching transistor is electrically connected to a control-signal terminal, a first conductive terminal of the fifth switching transistor is electrically connected to the driving-voltage terminal, a second conductive terminal of the fifth switching transistor is electrically connected to the first conductive terminal of the drive switching transistor, and the fifth switching transistor is configured to be turned on when receiving a control signal output by the control-signal terminal to control the drive current output by the driving-voltage terminal to be transmitted to the drive switching transistor; and
the light-emitting module comprises a light-emitting element, an anode of the light-emitting element is electrically connected to the fourth node, a cathode of the light-emitting element is electrically connected to a low-voltage terminal, and the light-emitting element is configured to receive the drive current and emit light according to the drive current.

16. The display panel of claim 15, wherein in a first period, the second switching transistor and the fifth switching transistor are turned on, the second node is charged to the first potential by the driving-voltage terminal, and at the same time, the third switching transistor and the fourth switching transistor are turned on, the first node is configured to receive the first reference-signal to raise a potential of the first node to a first reference-potential, and the fourth node is configured to receive the second reference-signal to raise a potential of the fourth node to a second reference-potential;
in a second period, the fifth switching transistor is turned off, the second switching transistor and the drive switching transistor are turned on, the second node is configured to discharge to the drive switching transistor through the second switching transistor and the third node, to drop the potential of the second node from the first potential to the second potential, to control the drive switching transistor to be turned off, a threshold voltage of the drive switching transistor is adjusted to a preset value when the drive switching transistor is turned off, and the second capacitor is configured to maintain the voltage of the second node;
in a third period, the second switching transistor is turned off and the data signal is transmitted to the first node through the third switching transistor and stored in the first capacitor; and
in a fourth period, the fifth switching transistor is turned on, the drive switching transistor is controlled to be turned on under control of the data signal, and the drive switching transistor is configured to receive the drive current from the fifth switching transistor and control the drive current to drive the light-emitting element to emit light.

17. The display panel of claim 16, wherein the first period and the second period are performed in a non-image-display phase, and the third period and the fourth period are performed in an image-display phase, wherein the non-image-display phase is a power-on non-display period.

18. The display panel of claim 16, wherein the first period and the second period are performed in a non-image-display phase, and the third period and the fourth period are performed in an image-display phase, wherein the non-image-display phase is a vertical blank period; and the vertical blank phase is located between image-display phases of two adjacent frames; and
the display panel is configured to perform the first period and the second period in a vertical blank phase of each frame; or the display panel is configured to perform the first period and the second period once in a vertical blank phase of every a frames, wherein a is an integer greater than 1.

19. A display device, comprising a power module and a display panel, wherein the power module is configured to provide driving power to the display panel to drive the display panel to perform image display, and the display panel comprises a substrate, a pixel definition layer, a partition structure, and a plurality of sub-pixels, and the pixel definition layer, the partition structure, and the plurality of sub-pixels are located on the substrate;
the pixel definition layer defines a plurality of pixel openings;
the plurality of sub-pixels are disposed in the plurality of pixel openings in one-to-one correspondence;
the partition structure is disposed on the pixel definition layer and surrounds each of the plurality of pixel openings;
the substrate comprises a first conductive layer, the first conductive layer comprises a plurality of reference voltage lines, and the plurality of reference voltage lines are configured to provide first reference-signals; and the first reference-signals are at least indicative of controlling the plurality of sub-pixels for image display; and
the partition structure comprises a second conductive layer, the second conductive layer comprises a plurality of first signal-lines; at least a part of the pixel definition layer is provided with a conductive portion, and the conductive portion penetrates through the pixel definition layer; and the plurality of first signal-lines are electrically connected to the plurality of reference voltage lines through the conductive portion.

20. The display device of claim 19, wherein the second conductive layer further comprises a plurality of second signal-lines, and the plurality of second signal-lines are configured to provide cathode signals to the plurality of sub-pixels; and
each of the plurality of sub-pixels comprises a first electrode-layer, a light-emitting layer, and a second electrode-layer that are sequentially laminated, the second electrode-layer is lap-jointed with adjacent two of the plurality of second signal-lines, and the second electrode-layer is isolated from the plurality of first signal-lines; and the plurality of first signal-lines and the plurality of second signal-lines are insulated from each other.
